(19) United States
(12) Patent Application Publication
(10) Pub. No.: US 2025/0176405 A1
(43) Pub. Date: May 29, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yanwei LU, Beijing (CN); Zhenli ZHOU, Beijing (CN); Zhuoran YAN, Beijing (CN); Yudiao CHENG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/843,378

(22) PCT Filed: Nov. 14, 2023
(86) PCT No.: PCT/CN2023/131546

§ 371 Date: Sep. 3, 2024

(30) Foreign Application Priority Data
Dec. 1, 2022 (CN) 202211539087.0

(51) Int. Cl. H10K 59/80; H10K 59/131; H10K 59/88

(52) U.S. Cl. CPC H10K 59/873; H10K 59/131; H10K 59/8722; H10K 59/88

(57) ABSTRACT

A display panel includes a display area and a peripheral area including a lead-out area, the lead-out area including a binding part. The display panel includes a driving backplane, light-emitting devices, encapsulation adhesives and an encapsulation cover plate. The driving backplane includes a substrate and a circuit layer; the circuit layer includes an encapsulation base and a power bus, which are distributed in a direction away from the substrate; the encapsulation base is arranged in the peripheral area and surrounds the display area; the power bus is at least partially located in the lead-out area; the portion of the power bus located in the lead-out area is located between the display area and the binding part, and is connected to the binding part; the encapsulation base at most overlaps with the portion of the power bus located in the lead-out area.

### CROSS-REFERENCE TO RELATED APPLICATIONS

The present disclosure is the U.S. national phase application of International Application No. PCT/CN2023/131546 filed on Nov. 14, 2023, which claims priority to Chinese Patent Application No. 202211539087.0, filed on Dec. 1, 2022 and entitled “DISPLAY PANEL AND DISPLAY DEVICE”, and the entire contents of both of which are incorporated herein by reference for all purposes.

### TECHNICAL FIELD

The present disclosure relates to the field of display technology, in particular, to a display panel and a display device.

### BACKGROUND

A display panel is an indispensable component of an electronic device such as a mobile phone. A widely used organic light-emitting diode (OLED) display panel adopts organic light-emitting diodes as light-emitting devices. In the related art, in order to prevent external water and oxygen from corroding the light-emitting devices, it is necessary to have the light-emitting devices to be encapsulated. However, the encapsulating effect of the existing encapsulating methods needs to be improved.

It should be noted that the information disclosed in above section is only for the purpose of enhancing the understanding of the background of the present disclosure, and thus can include information that does not constitute prior art already known to those of ordinary skill in the art.

### SUMMARY

The present disclosure provides a display panel and a display device.

According to one aspect of the present disclosure, a display panel is provided. The display panel includes a display area and a peripheral area located outside the display area, wherein the peripheral area includes a lead-out area, and the lead-out area includes a binding part, and wherein the display panel includes: a driving backplane including a substrate and a circuit layer arranged on a side of the substrate, wherein the circuit layer includes an encapsulation base and a power bus that are arranged along a direction away from the substrate, the encapsulation base is arranged in the peripheral area and at least partially surrounds the display area, the power bus is at least partially located in the lead-out area, and a portion of the power bus located in the lead-out area is between the display area and the binding part and is connected to the binding part, and wherein the encapsulation base at most overlaps with the portion of the power bus located in the lead-out area, and the encapsulation base is a reflective structure; a light-emitting device arranged on a side of the circuit layer away from the substrate, wherein the light-emitting device is located in the display area; an encapsulation adhesive at least partially provided on a surface of the encapsulation base away from the substrate, wherein the encapsulation adhesive at least partially surrounds the display area along an extension trajectory of the encapsulation base; and an encapsulation cover plate arranged on a surface of the encapsulation adhesive away from the substrate.

In some embodiments of the present disclosure, the encapsulation base includes a transfer part in the lead-out area, and the power bus includes a first bus portion and a second bus portion, and wherein the first bus portion is at least partially located on a side of the transfer part close to the display area, the second bus portion is at least partially located on a side of the transfer part away from the display area and is connected to the binding part, and the first bus portion and the second bus portion are both connected to the transfer part.

In some embodiments of the present disclosure, the transfer part includes a first transfer part and a second transfer part arranged along a first direction in a spaced manner, and the power bus includes a first power bus and a second power bus, and wherein a first bus portion of the first power bus and a second bus portion of the first power bus are connected through the first transfer part, and a first bus portion of the second power bus and a second bus portion of the second power bus are connected through the second transfer part.

In some embodiments of the present disclosure, the circuit layer further includes multiple first signal lines, and the first signal lines are at least partially located in the lead-out area and located between the display area and the binding part, and wherein portions of the first signal lines located in the lead-out area include first segments extending along the first direction and second segments extending along a second direction intersecting with the first direction, and the second segments are connected to the first segments and the binding part.

In some embodiments of the present disclosure, the peripheral area further includes side areas arranged on both sides of the display area along the first direction and a top area arranged on a side of the display area away from the lead-out area, and the encapsulation base includes a base body located in the side areas and the top area, at least some sections of the first segments, and at least some sections of the second segments; and wherein the second segments of the first signal lines include two signal line groups symmetrically about a central axis of the binding part that is along the second direction, and the first transfer part is located between the two signal line groups.

In some embodiments of the present disclosure, the peripheral area further includes side areas arranged on both sides of the display area along the first direction and a top area arranged on a side of the display area away from the lead-out area along the second direction; and wherein the first segments are located between the transfer part and the display area, and the second segments and the transfer part are distributed along the first direction; and wherein the encapsulation base includes a base body located in the side areas and the top area, and at least some sections of the second segments; and wherein the second segments of the first signal lines are divided into two signal line groups symmetrically about a central axis of the binding part that is along the second direction, and the transfer part is located outside the two signal line groups.

In some embodiments of the present disclosure, the encapsulation base further includes a first dummy part, and the first dummy part is arranged between the first transfer part and the second transfer part along the first direction in a spaced manner, and wherein the encapsulation adhesive covers the first dummy part.

In some embodiments of the present disclosure, a second dummy part is arranged between the second segments belonging to the encapsulation base, and the encapsulation adhesive covers the second dummy part.

In some embodiments of the present disclosure, the first dummy part and the second dummy part both extend along the second direction.

In some embodiments of the present disclosure, at least a portion of the second segments belonging to the encapsulation base extend along a bent trajectory.

In some embodiments of the present disclosure, at least a portion of the second segments belonging to the encapsulation base include a first bent portion and a second bent portion that are bent along a first direction in a reverse manner, and the first bent portion and the second bent portion are alternately distributed along a second direction.

In some embodiments of the present disclosure, the circuit layer further includes multiple first signal lines, and the first signal lines are at least partially located in the lead-out area and located between the display area and the binding part, and wherein portions of the first signal lines located in the lead-out area include first segments extending along a first direction and second segments extending along a second direction, and the second segments are connected to the first segments and the binding part; and wherein the power bus located in the lead-out area includes a first bus portion extending along the first direction and a second bus portion extending along the second direction, the second bus portion is connected to the first bus portion and the binding part, the first bus portion is located between the first signal lines and the display area, the second bus portion overlaps with the first segments, and the encapsulation adhesive covers the second bus portion.

In some embodiments of the present disclosure, the second bus portion is provided with multiple first through holes, and the encapsulation adhesive is filled in the first through holes.

In some embodiments of the present disclosure, a width of the second bus portion along the first direction is not greater than 300 μm.

In some embodiments of the present disclosure, some areas in the encapsulation base are provided with a second through hole.

In some embodiments of the present disclosure, the second through hole is filled with a filling layer, and the filling layer is provided with multiple third through holes, and wherein the encapsulation adhesive is filled in each of the third through holes.

In some embodiments of the present disclosure, the circuit layer includes a first gate layer, a first gate insulation layer, a second gate layer, an interlayer dielectric layer, a first source and drain layer, a first flattened layer, a second source and drain layer, and a second flattened layer that are arranged in sequence along a direction away from the substrate, and the light-emitting device is located on a surface of the second flattened layer away from the substrate; and wherein the encapsulation base is located in the first gate layer or the second gate layer, and the power bus is located in the first source and drain layer or the second source and drain layer.

According to one aspect of the present disclosure, a display device is provided. The display device includes a display panel as described in any of the above.

It should be understood that the general description in the above and the detailed description in the following are only illustrative and explanatory, and do not limit the present disclosure.

### BRIEF DESCRIPTION OF THE DRAWINGS

The drawings herein, which are incorporated in and constitute a portion of this specification, illustrate embodiments consistent with the present disclosure and serve together with the specification to explain principles of the present disclosure. It is apparent that the drawings in the following description are only some embodiments of the present disclosure, and other drawings can be obtained based on the drawings by those of ordinary skill in the art without creative effort.

FIG. 1 is a top view of a display panel according to embodiments of the present disclosure.

FIG. 2 is a schematic diagram of wiring of a display panel according to embodiments of the present disclosure.

FIG. 3 is a cross-sectional schematic diagram of a display panel according to embodiments of the present disclosure.

FIG. 4 is a partial cross-sectional schematic diagram of a display area in a display panel according to embodiments of the present disclosure.

FIG. 5 is a cross-sectional schematic diagram of a display panel according to embodiments of the present disclosure.

FIG. 6 is a partial schematic diagram of FIG. 5.

FIG. 7 is a cross-sectional schematic diagram of a display panel according to embodiments of the present disclosure.

FIG. 8 is a cross-sectional schematic diagram of a display panel according to embodiments of the present disclosure.

FIG. 9 is a partial top view of an encapsulation base in a display panel according to embodiments of the present disclosure.

FIG. 10 is a partial top view of a substrate body in a display panel according to embodiments of the present disclosure.

FIG. 11 is a partial top view of an encapsulation base in a display panel according to embodiments of the present disclosure.

FIG. 12 is a partial top view of a lead-out area in a display panel according to embodiments of the present disclosure.

FIG. 13 is a partial top view of an encapsulation base in a display panel according to embodiments of the present disclosure.

### DETAILED DESCRIPTION

Example embodiments will now be described more fully with reference to the drawings. However, the example embodiments can be implemented in a variety of forms and should not be construed as being limited to the embodiments set forth herein. Rather, the provision of these embodiments makes the present disclosure comprehensive and complete and conveys ideas of the example embodiments in a comprehensive manner to those skilled in the art. The same reference numerals in the drawings indicate the same or similar structures, and thus their detailed description will be omitted. In addition, the drawings are only schematic illustrations of the present disclosure and are not necessarily drawn to scale.

Terms “a”, “an”, “the”, “said” and “at least one” are used to indicate presence of one or more elements/components/etc. Terms “include” and “comprise” are used to indicate an open-ended inclusion, and mean presence of additional elements/components/etc., in addition to listed elements/components/etc. Terms “first”, “second”, “third”, etc., are used as markings only, instead of limiting the number of objects.

A first direction X and a second direction Y herein are only two directions that are perpendicular to each other or intersect at other angles. In the drawings of the present disclosure, the first direction X can be horizontal and the second direction Y can be vertical, but is not limited to this. If the display panel rotates, the actual orientation of the first direction X and the second direction Y may change.

That a feature A overlaps with a feature B herein refers to an orthographic projection of the feature A on the substrate at least partially overlaps with an orthographic of the feature B on the substrate.

Embodiments of the present disclosure provide a display panel, as shown in FIGS. 1-3. The display panel includes a display area AA and a peripheral area WA outside the display area AA. The peripheral area WA includes a lead-out area FA, and the lead-out area FA includes a binding part BA.

The display panel includes a driving backplane BP. The driving backplane BP includes a substrate SU and a circuit layer TL provided on a side of the substrate SU. The circuit layer TL includes an encapsulation base TB and a power bus, which are distributed along a direction away from the substrate SU. The encapsulation base TB is provided in the peripheral area WA and at least partially surrounds the display area AA. The power bus is located at least partially in the lead-out area FA, and the portion of the power bus located in the lead-out area FA is located between the display area AA and the binding part BA, and is connected to the binding part BA. The encapsulation base TB at most overlaps with the portion of the power bus located in the lead-out area FA. The encapsulation base TB is a reflective structure.

The display panel further includes a light-emitting device LD. The light-emitting device LD is located on a side of the circuit layer TL away from the substrate SU and located in the display area AA.

The display panel further includes an encapsulation adhesive FR. The encapsulation adhesive FR is at least partially provided on a surface of the encapsulation base TB away from the substrate SU, and at least partially surrounds the display area AA along an extension trajectory of the encapsulation base TB.

The display panel further includes an encapsulation cover plate CG. The encapsulation cover plate CG is provided on a surface of the encapsulation adhesive FR away from the substrate SU.

According to the display panel provided by embodiments of the present disclosure, the light-emitting device LD can be covered through the encapsulation cover plate CG and sealed with the encapsulation adhesive FR, thereby protecting the light-emitting device LD. Since the reflective encapsulation base TB is arranged in the peripheral area WA, and the encapsulation adhesive FR is arranged on the encapsulation base TB, the light intensity on the encapsulation adhesive FR can be enhanced, the curing degree of the encapsulation adhesive FR can be improved, and the connection between the encapsulation cover plate CG and the driving backplane BP can be made tighter and more secure, thereby improving the encapsulating effect. In addition, by providing the encapsulation base TB to support the encapsulation adhesive FR, it is conducive to improving the flatness of the surface where the encapsulation adhesive FR is located, and reducing the risk of cracks occurring in the drop ball test due to the presence of a large step difference in the area covered by the encapsulation adhesive FR, and thus improving the product yield.

The display panel provided by the present disclosure will be explained in detail in the following.

As shown in FIG. 1, the display area AA of the display panel is an area that can emit light and is used for displaying images. The peripheral area WA is located outside the display area AA. The peripheral area WA can be a continuous or discontinuous annular area surrounding the display area AA, or a semi enclosed area of a “U” shape. The shape of the peripheral area WA is not specifically limited here. The peripheral area WA can include a lead-out area FA, and the lead-out area FA has a binding part BA. The binding part BA can be connected to a flexible circuit board. The flexible circuit board can be connected to a control circuit board, and the control circuit board can transmit signals to the binding part BA through the flexible circuit board.

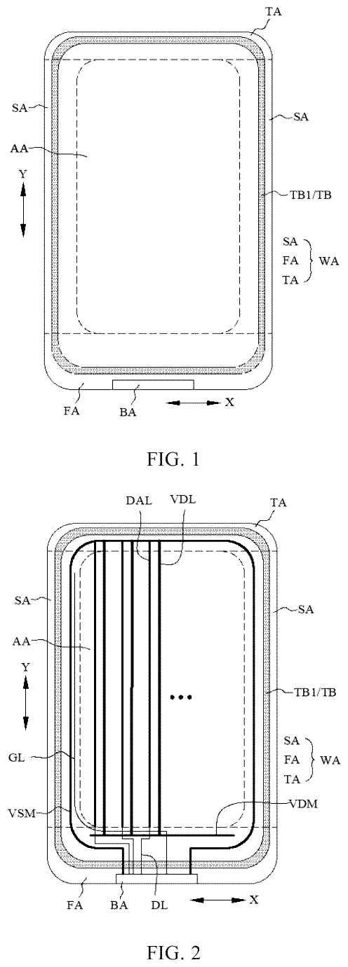

As shown in FIGS. 1 and 2, in some embodiments of the present disclosure, the peripheral area WA can be divided into multiple areas, including a lead-out area FA surrounding outside the display area AA, two side areas SA, and a top area TA. The two side areas SA can be distributed on both sides of the display area AA along a first direction X and can be symmetrically arranged about a central axis of the display area AA along a second direction Y. The top area TA and the lead-out area FA can be distributed on both sides of the display area AA along the second direction Y. That is, the top area TA is located on a side of the display area AA away from the lead-out area. The lead-out area FA, the two side areas SA, and the top area TA can be connected to form the annular peripheral area WA surrounding the display area AA.

The display area AA and the peripheral area WA mentioned above are divided based on their functions, rather than limiting the boundaries of entities used to implement partitioning in the display panel.

As shown in FIGS. 2-4, the driving backplane BP has a driving circuit for driving the light-emitting devices LD to emit light. The driving circuit can include a pixel circuit located in the display area AA and a peripheral circuit located in the peripheral area WA.

The number of pixel circuits can be multiple, and the multiple pixel circuits are distributed in an array in multiple rows and columns along the first direction X and the second direction Y. One pixel circuit can be connected to one light-emitting device LD. In some embodiments, one pixel circuit can also be connected to multiple light-emitting devices LD. Embodiments of the present disclosure will take the example of one-to-one correspondence between the pixel circuit and the light-emitting device LD only for explanation.

The pixel circuit can include multiple transistors and capacitors, and the pixel circuit can be structures of 3T1C, 7T1C, 8T1C, etc., with nTmC representing one pixel circuit consisting of n transistors (represented by the letter “T”) and m capacitors (represented by the letter “C”).

The peripheral circuit can be connected to the pixel circuit and the light-emitting device LD, and can control the current passing through the light-emitting device LD through the pixel circuit, thereby controlling the brightness of the light-emitting device LD. The peripheral circuit can include multiple transistors and capacitors, and can include the gate driving circuit, the light-emitting controlling circuit, etc. In some embodiments, the peripheral circuit can also include other circuits, and the specific structure of the peripheral circuit is not specifically limited here.

The above pixel circuit can adopt LTPS (Low Temperature Polycrystalline Silicon) technology, which means that all transistors in the pixel circuit are low-temperature polycrystalline silicon transistors. In some embodiments, the pixel circuit can also adopt LTPO (LTPS+Oxide) technology, which is not specifically limited here.

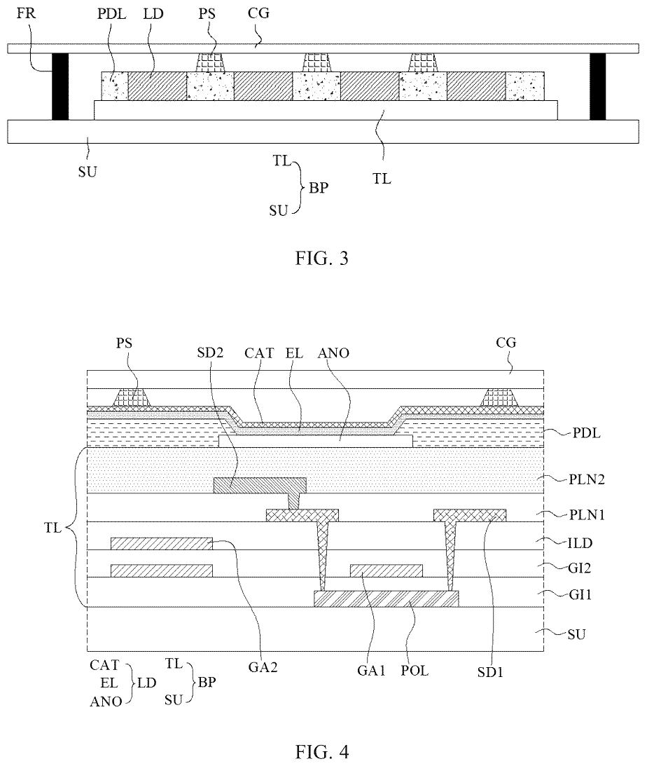

The film layers of the driving backplane BP will be exemplarily explained in the following. As shown in FIGS. 3 and 4, the driving backplane BP can include a substrate SU and a circuit layer TL.

The substrate SU can be the substrate of the driving backplane BP, which can carry pixel circuits and peripheral circuits. The substrate SU can be a hard structure or a flexible structure, and the substrate SU can be a single-layer structure or a multi-layer structure, which are not specifically limited here.

The circuit layer TL is provided on a side of the substrate SU and can include various transistors and capacitors of the driving circuit.

As shown in FIG. 4, in some embodiments of the present disclosure, the circuit layer TL can include a semiconductor layer POL, a first gate insulation layer GI1, a first gate layer GA1, a second gate insulation layer GI2, a second gate layer GA2, an interlayer dielectric layer ILD, a first source and drain layer SD1, a first flattened layer PLN1, a second source and drain layer SD2, and a second flattened layer PLN2, which are stacked in sequence along a direction away from the substrate SU.

The semiconductor layer POL can be arranged on a side of the substrate SU and includes channels of the transistors. The material of the semiconductor layer POL can be polycrystalline silicon.

The first gate insulation layer GI1 can cover the semiconductor layer POL, and the material of the first gate insulation layer GI1 can be insulation materials such as silicon nitride, silicon oxide, etc.

The first gate layer GA1 can be arranged on a surface of the first gate insulation layer GI1 away from the substrate SU, and includes gates of the transistors and the first electrode plate of the capacitor.

The second gate insulation layer GI2 can cover the first gate layer GA1, and the material of the second gate insulation layer GI2 can be insulation materials such as silicon nitride, silicon oxide, etc.

The second gate layer GA2 can be arranged on a surface of the second gate insulation layer GI2 away from the substrate SU, and includes the second electrode plate of the capacitor. The second electrode plate overlaps with the first electrode plate to form the capacitor.

The interlayer dielectric layer ILD can cover the second gate layer GA2, and the material of the interlayer dielectric layer ILD can include inorganic insulation materials such as silicon nitride, silicon oxide, silicon oxynitride, etc., which are not specifically limited here.

The first source and drain layer SD1 can be arranged on a surface of the interlayer dielectric layer ILD away from the substrate SU. The first source and drain layer SD1 can be a single-layer structure or a multi-layer structure, and the material of the first source and drain layer SD1 can include one or more metals such as Ti, Al, Mg, Ag, etc. In some embodiments, the first source and drain layer SD1 can include a first sub-layer, a second sub-layer, and a third sub-layer stacked in sequence along a direction away from the substrate SU, the first sub-layer and the third sub-layer can be made of the same metal material, such as Ti, and the second sub-layer can be made of a different metal material from that of the first sub-layer and the third sub-layer, such as A1.

The first flattened layer PLN1 can be arranged on a side of the first source and drain layer SD1 away from the substrate SU, and the material of the first flattened layer PLN1 can be insulation materials such as resin. In addition, the circuit layer TL can further include a passivation layer that can cover the first source and drain layer SD1, and the first flattened layer PLN1 can cover the passivation layer. In some embodiments, the first flattened layer PLN1 can also directly cover the first source and drain layer SD1.

The second source and drain layer SD2 can be arranged on a surface of the first flattened layer PLN1 away from the substrate SU. The second source and drain layer SD2 can be a single-layer structure or a multi-layer structure, and the material of the second source and drain layer SD2 can include one or more metals such as Ti, Al, Mg, Ag, etc. In some embodiments, the second source and drain layer SD2 can be of the three-layer structure the same as that of the first source and drain layer SD1.

The second flattened layer PLN2 can cover the second source and drain layer SD2, and the material of the second flattened layer PLN2 can be insulation materials such as resin.

As shown in FIG. 2, the circuit layer TL can include multiple lines for transmitting signals, including multiple power lines VDL and data lines DAL. The power line VDL can extend along the second direction Y, and at least a portion of any power line VDL is located within the display area AA. The power lines VDL can be distributed along the first direction X at intervals, one column of pixel circuits can be connected to one power line VDL, and a first power signal can be transmitted to the pixel circuits through the power line VDL. The data line DAL is located at least partially within the display area AA. One column of pixel circuits can be connected to one data line DAL, and a data signal can be transmitted to the pixel circuits through the data line DAL, to control the brightness of the light-emitting devices LD. In some embodiments, the power lines VDL and the data lines DAL can be located in the second source and drain layer SD2.

As shown in FIG. 2, the circuit layer TL can further include a power bus located in the peripheral area WA. The power bus is at least partially located in the lead-out area FA, and the portion of the power bus located in the lead-out area FA is located between the display area AA and the binding part BA, and is connected to the binding part BA. The power bus can include a first power bus VDM and a second power bus VSM.

The first power bus VDM is located at least partially in the lead-out area FA and is located between the display area AA and the binding part BA. Each power line VDL is connected to the first power bus VDM, so that the first power signal can be transmitted to each power line VDL through the first power bus VDM. In some embodiments, in order to input the first power signal to the first power bus VDM, the first power bus VDM can be connected to the binding part BA, and the first power signal can be transmitted to the first power bus VDM through the binding part BA.

The second power bus VSM is located at least partially in the lead-out area FA, and is located between the display area AA and the binding part BA. The second power bus VSM is connected to the binding part BA, and a second power signal can be transmitted to the second power bus VSM through the binding part BA.

The first power bus VDM and the second power bus VSM can be arranged in the same layer, and both of them can be located in the first source and drain layer SD1 or the second source and drain layer SD2.

The binding part BA can include multiple pads spaced along the first direction X, and one pad can be connected to one line, and the line here can be the first power bus VDM, the second power bus VSM, a first signal line DL, a second signal line GL, etc. The pad can be used to bind with the flexible circuit board. Alternatively, the pad can also be a pin of a driver chip arranged on the driver backplane BP, and the structure of the binding part BA is not specifically limited here.

As shown in FIG. 2, in some embodiments of the present disclosure, the first power bus VDM can be entirely located in the lead-out area FA, or can extend from the lead-out area FA to the side area SA. The second power bus VSM can extend at least from the side area SA to the lead-out area FA. In some embodiments, the second power bus VSM can extend from the top area TA, passing through the side area SA, to the lead-out area FA, and be connected to the binding part BA. The second power bus VSM can be symmetrical about the central axis of the display area AA along the second direction Y. The second power bus VSM is located outside the first power bus VDM, that is, the first power bus VDM is located within the range surrounded by the second power bus VSM. The second power bus VSM can extend from the two side areas SA to the lead-out area FA and be connected to the binding part BA. The position where the first power bus VDS is connected to the binding part BA is located between the two positions where the second power bus VSM is connected to the binding part BA.

In some embodiments, as shown in FIG. 2, the circuit layer TL can further include multiple first signal lines DL and second signal lines GL.

The first signal lines DL are at least partially located within the lead-out area FA, and one first signal line DL can be connected to one data line DAL. The first signal line DL can be connected to the binding part BA to transmit data signals to the data lines DAL through the binding part BA. The first signal lines DL are located between the display area AA and the binding part BA, and the portion of any first signal line DL located in the lead-out area FA can include a first segment DL1 extending along the first direction X and a second segment DL2 extending along the second direction Y. One end of the first segment DLI can be connected to the data line DAL, the other end of the first segment DLI can be connected to the second segment DL2, and the second segment DL2 can be connected to the binding part BA. The first signal line DL can be located in either the first gate layer GA1 or the second gate layer GA2. Therefore, the first power bus VDM and the second power bus VSM can be located on a side of the first signal line DL away from the substrate SU and can overlap with the first signal line DL.

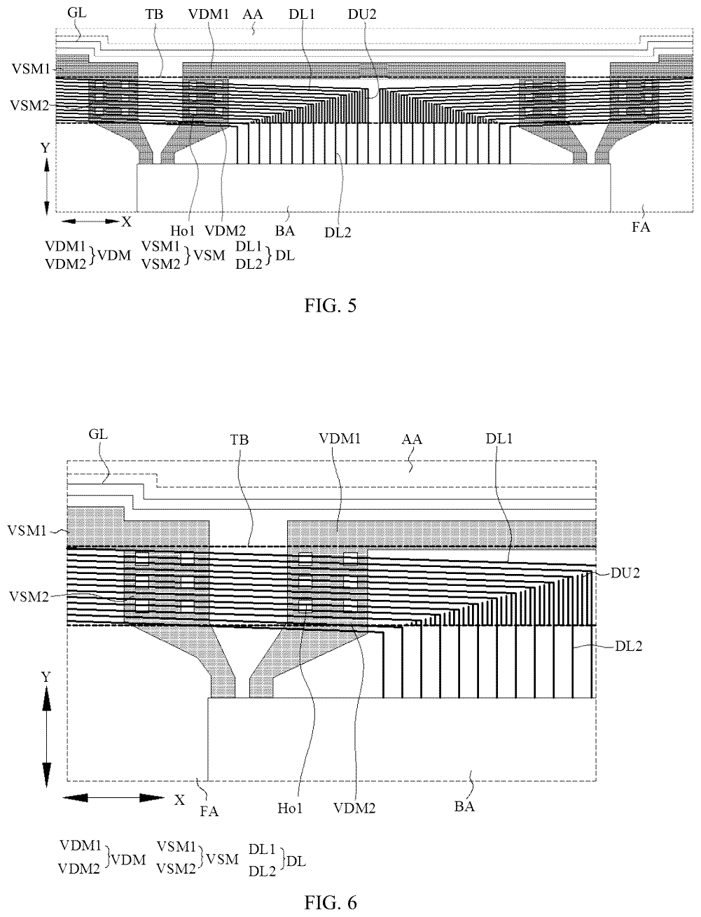

It should be noted that extension directions of the first segment DL1 and the second segment DL2 of the first signal line DL refer to directions of the extension trend of the two segments, and are not limited to strictly parallel to the directions of the straight lines and the arrows shown by the first direction X and the second direction Y in the drawings. For example, in FIG. 8, there is an angle between the first segment DL1 and the straight line shown by the first direction X, but the first segment DL1 still extends from one side of the display panel to the other side of the display panel along the first direction X. Therefore, in some embodiments of the present disclosure, the extension direction of the first segment DL1 in FIGS. 5-8 can still be defined as the first direction X. An end where the first segment DL1 is connected to the second segment DL2 can be skewed towards the binding part BA. In some embodiments, the first segment DL1 can also extend parallel to the straight line shown by the first direction X in the drawings.

As shown in FIG. 2, the second signal line GL can be connected to the peripheral circuit. In some embodiments, the second signal line GL can be connected to a gate driving circuit and the light-emitting controlling circuit, and one gate driving circuit and one light-emitting controlling circuit can be simultaneously connected to multiple second signal lines GL. Different second signal lines GL can transmit different signals. Each second signal line GL can extend at least from the side area SA to the lead-out area FA and be connected to the binding part BA. The second signal line GL can be located in the first source and drain layer SD1 or the second source and drain layer SD2, so that the second signal lines GL are located on sides of the first signal lines DL where the first signal lines DL are close to the display area AA. In some embodiments, the second signal line GL and the power line can both be located in the first source and drain layer SD1.

As shown in FIG. 4, the light-emitting devices LD can be located on one side of the driving backplane BP. In some embodiments, the light-emitting devices LD can be located on a surface of the second flattened layer PLN2 away from the substrate SU. Each of the light-emitting devices LD is located within the display area AA, and the light-emitting device LD can be an OLED (organic light-emitting diode). In some embodiments, the light-emitting device LD can also be a Micro LED (micron light-emitting diode), a Mini LED (submicron light-emitting diode), a QLED (quantum dot diode), or other light-emitting devices.

In some embodiments, the light-emitting device LD can include a first electrode ANO, an electro-luminescence layer EL, and a second electrode CAT, which are stacked along a direction away from the driving backplane BP. The first electrodes ANO can be located on a side of the driving backplane BP and are arranged in an array. In some embodiments, the first electrodes ANO can be located on a surface of the second flattened layer PLN2 away from the substrate SU. The first electrode ANO is connected to the pixel circuit. The electro-luminescence layer EL can include a hole injection layer, a hole transport layer, a luminescent material layer, an electron transport layer, and an electron injection layer, which are stacked along a direction away from the driving backplane BP. Each of the light-emitting devices LD can share the second electrode CAT, which means that the second electrode CAT can be a continuous integral layer structure.

The second electrode CAT can be connected to the second power bus VSM in the peripheral area WA, so that the second power signal can be applied to the second electrode CAT through the second power bus VSM.

In some embodiments, as shown in FIGS. 3 and 4, in order to limit the light-emitting range of the light-emitting device LD and prevent crosstalk, a pixel definition layer PDL can be provided on a surface where the first electrode ANO is arranged. The pixel definition layer PDL is located within the display area AA, the pixel definition layer PDL can have openings exposing each first electrode ANO, and the electro-luminescence layer EL and the first electrode ANO are stacked within the openings. In some embodiments, the pixel definition layer PDL and the first electrode ANO are both located on a surface of the second flattened layer PLN2 away from the substrate SU. The opening of the pixel definition layer PDL used to expose the first electrode ANO can be smaller than the first electrode ANO. Due to the fact that the electro-luminescence layer EL has an integral layer structure, it is not only that the electro-luminescence layer EL stacks with the first electrode ANO within the opening, but also it covers the pixel definition layer PDL.

The luminescent material layers of different light-emitting devices LD are spaced apart from each other, allowing the light-emitting devices LD to directly emit monochromatic light, and different light-emitting devices LD can emit light of different colors, thereby achieving color display. In some embodiments, the luminescent material layer of the light-emitting devices LD can also be a continuous integral layer structure, allowing different light-emitting devices LD to emit light of the same colors, and the color display can be achieved by using the filter layer CFL located on a side of the light-emitting device LD away from the driving backplane BP.

As shown in FIGS. 3 and 4, the display panel can further include the encapsulation adhesive FR and the encapsulation cover plate CG.

The encapsulation of the light-emitting device LD in the display area AA can be achieved by adhering the encapsulation cover plate CG with the driving backplane by using the encapsulation adhesive FR, so that the erosion of the light-emitting device LD by external water and oxygen can be prevented.

The encapsulation adhesive FR can have an annular structure that surrounds the display area AA. That is, the encapsulation adhesive FR can extend to all of the top area TA, the side areas SA, and the lead-out area FA. In some embodiments, the encapsulation adhesive FR is located in the lead-out area FA, on a side of the binding part BA close to the display area AA.

The encapsulation cover plate CG can be made of transparent hard materials such as glass or acrylic, and can be adhered to a surface of the encapsulation adhesive FR away from the substrate SU. The material of the encapsulation adhesive FR can be frit adhesive, which can be obtained by mixing the glass powder with the solvent, and melted after laser sintering, so as to achieve sealing and adhering. In some embodiments, inert gas can be filled into the space enclosed by the encapsulation cover plate CG, the driving backplane BP, and the encapsulation adhesive FR.

In some embodiments, in order to support the encapsulation cover plate CG, the number of support pillars PS can be multiple. The multiple support pillars PS are distributed on a side of the light-emitting device LD away from the driving backplane BP in an array, and at least some of the support pillars PS are located in the display area AA. The support pillars PS can be directly arranged on a surface of the pixel definition layer PDL away from the substrate SU, and the second electrode CAT covers the support pillars PS and protrudes at the positions corresponding to the support pillars PS. In some embodiments, the support pillars PS can also be arranged on a surface of the second electrode CAT away from the substrate SU.

The encapsulation cover plate CG can be arranged on a side of the support pillars PS away from the driving backplane BP. In some embodiments, the encapsulation cover plate CG can be placed on the second electrode CAT lifted up by the support pillars PS, and can directly contact the support pillars PS arranged on the surface of the second electrode CAT away from the substrate SU.

As shown in FIG. 2, in order to improve the encapsulating effect, the circuit layer TL can include an encapsulation base TB. The encapsulation base TB is arranged in the peripheral area WA and arranged around the display area AA. The encapsulation base TB at most overlaps with the portion of the power bus located in the lead-out area. The encapsulation adhesive FR can be provided on a surface of the encapsulation base TB away from the substrate SU, and can extend along the extension trajectory of the encapsulation base TB, so that the encapsulation adhesive FR can be supported by the encapsulation base TB. In some embodiments, the encapsulation base TB is a reflective structure, which can improve the curing degree of the encapsulation adhesive FR through the reflection of the encapsulation base TB, making the encapsulation adhesive FR more secure, thereby improving the sealing effect.

As shown in FIG. 2, the encapsulation base TB is located in the top area TA, the side areas SA, and the lead-out area FA, and the encapsulation base TB is located outside the second signal line GL. The encapsulation base TB can be located in the first gate layer GA1 or the second gate layer GA2. In some embodiments, the encapsulation base TB and the first signal line DL are located in the first gate layer GA1, the power bus is located in the first source and drain layer SD1, and thus the power line is located on a side of the encapsulation base TB away from the substrate SU. In some embodiments, the encapsulation base TB can include multiple spaced portions distributed around the display area AA, rather than necessarily a continuous annular structure. In some embodiments, at least a portion of the encapsulation base TB can utilize a local section of the first signal line DL or other wirings.

The encapsulation base TB can include a base body TB1, which is located in the side areas SA and the top area TA, and is located on a side of the second signal line GL away from the display area AA. That is, the base body TB1 is located outside the second signal line GL. The partial section of the first signal line DL within the lead-out area FA can be used as a portion of the encapsulation base TB, which means that the encapsulation base TB can include the base body TB1 and some sections of the first signal line DL.

It is found that if the power bus overlaps with the encapsulation base TB in the lead-out area FA, and if the encapsulation adhesive FR not only covers the portion of the encapsulation base TB that does not overlap with the power bus, but also covers the portion of the power bus that overlaps with the encapsulation base TB, compared to the encapsulation base TB that does not overlap with the power bus, there will be a height difference (i.e., a step difference) existed between the power bus that overlaps with the encapsulation base TB and the encapsulation base TB that does not overlap with the power bus, which causes climbing and dropping of the encapsulation adhesive FR. As a result, during the ball drop test, uneven force will easily occur due to the presence of the dropping of the encapsulation adhesive FR, resulting in cracks and test failure, and the product yield needs to be improved. Therefore, embodiments of the present disclosure propose to reduce or eliminate the overlapping area between the power bus and the encapsulation base TB, so that the encapsulation adhesive FR can be located as much as possible on the surface of the encapsulation base TB away from the substrate SU.

Embodiments of the present disclosure will be exemplarily explained based on the structure and distribution of the encapsulation base TB.

As shown in FIGS. 5 and 6, in some embodiments of the present disclosure, the portion of the power bus located in the lead-out area FA can include a first bus portion and a second bus portion. The first bus portion extends along the first direction X and is located between the first signal line DL and the second signal line GL. The second bus portion can extend along the second direction Y, and can be connected to the first bus portion and the binding part BA. The second bus portion overlaps with the first segment DL1 of the first signal line DL, and the encapsulation adhesive FR can cover the second bus portion.

As shown in FIGS. 5 and 6, in some embodiments, the first bus portion VDM1 of the first power bus VDM and the first bus portion VSM1 of the second power bus VSM can be arranged along the first direction X and located between the display area AA and the first segments DL1 of the first signal lines DL. The second bus portion VDM2 of the first power bus VDM and the second bus portion VSM2 of the second power bus VSM can extend along the second direction Y and be connected to the binding part BA.

The second bus portion VDM2 and the second bus portion VSM2 overlap with the first segment DL1, and such first segment DL1 forms a portion of the encapsulation base TB. In other words, the first power bus VDM and the second power bus VSM only overlap with the encapsulation base TB in the second bus portion VDM2 and the second bus portion VSM2, while the first bus portion VDM1 and the first bus portion VSM1 do not overlap with the encapsulation base TB. The encapsulation adhesive FR covers the encapsulation substrate TB as well as the second bus portion VDM2 and the second bus portion VSM2. By designing the structure of the power bus, that the first power bus VDM and the second power bus VSM both overlap with the encapsulation base TB can be avoided, thereby reducing the overlapping area, reducing the portions of the first power bus VDM and the second power bus VSM directly covered by the encapsulation adhesive FR, and reducing the range of the step difference, which is conducive to narrowing down the range in which the cracks occur, and improving the product yield.

In some embodiments, the widths of the second bus portion VDM2 and the second bus portion VSM2 in the first direction X can be made no greater than 300 μm to avoid excessive overlapping range.

In some embodiments, as shown in FIGS. 5 and 6, the second bus portion VDM2 and the second bus portion VSM2 can be provided with multiple first through holes Ho1, and the encapsulation adhesive FR can be filled in the first through holes Ho1, and thus increasing the contact surfaces between the encapsulation adhesive FR and the second bus portions VDM2 and VSM2, increasing the complexity of the cross-section, which is conducive to blocking water and oxygen, thereby improving the sealing effect.

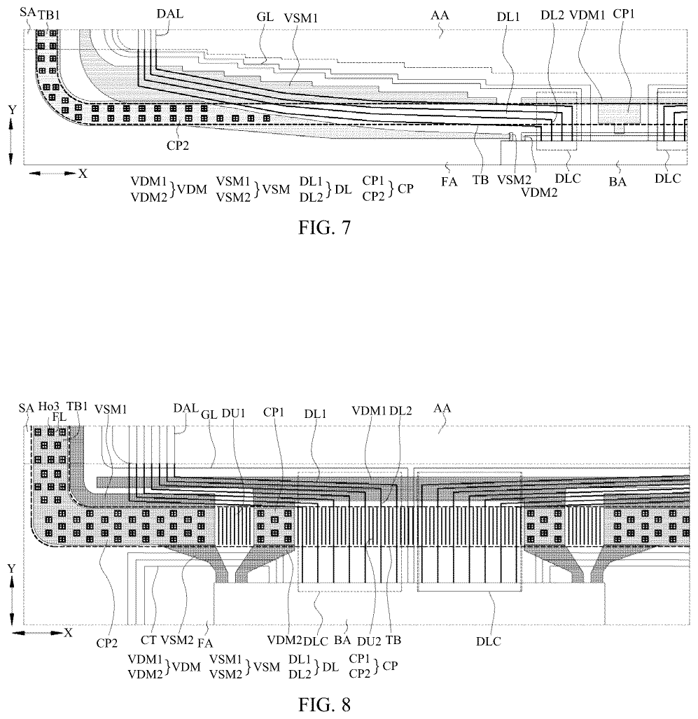

As shown in FIGS. 7 and 8, in some embodiments of the present disclosure, the power bus can be prevented from overlapping with the encapsulation base TB in the lead-out area FA, so that the encapsulation adhesive FR is located on the surface of the encapsulation base TB away from the substrate SU, and the power bus is located outside the coverage range of the encapsulation adhesive FR, thereby eliminating the step difference caused by overlapping between the power bus and the encapsulation adhesive FR, and reducing the risk of the cracks occurring. In some embodiments, the encapsulation base TB can include a transfer part CP in the lead-out area FA, and the power bus is divided into a first bus portion and a second bus portion, which are located on both sides of the transfer part CP. The first bus portion and the second bus portion can be connected through the transfer part CP, so that the encapsulation base TB does not overlap with the power bus, thereby eliminating the step difference in the encapsulation adhesive FR.

Embodiments will be explained in the following.

As shown in FIG. 7, in some embodiments of the present disclosure, the first segment DL1 of each first signal line DL is located between the power bus and the binding part BA, the first bus portion is at least partially located on a side of the transfer part CP close to the display area AA, and the second bus portion is at least partially located on a side of the transfer part CP away from the display area AA and is connected to the binding part BA. The first bus portion and the second bus portion are located on a surface of the transfer part CP away from the substrate SU, and both the first bus portion and the second bus portion are connected to the transfer part. The encapsulation adhesive FR covers the transfer part CP, and the transfer part CP forms a portion of the encapsulation substrate TB, so that the encapsulation adhesive FR does not need to cover the power bus.

As shown in FIG. 7, in some embodiments, the transfer part CP is located on a side of the first signal lines DL away from the display area AA. The transfer part CP and at least some sections of the first signal lines DL are arranged along the first direction X, and these sections of the first signal lines DL form a portion of the encapsulation base TB. The first bus portion of the power bus is located on a side of the transfer part CP close to the display area AA, and the second bus portion of the power bus is located between the transfer part CP and the binding part BA and is connected to the binding part BA. The first bus portion and the second bus portion are connected through the transfer part CP.

In some embodiments, the transfer part CP can include a first transfer part CP1 and a second transfer part CP2 distributed at intervals along the first direction X. The power bus can include the first power bus VDM and the second power bus VSM. The first bus portion VDM1 and the second bus portion VDM2 of the first power bus VDM are connected through the first transfer part CP1. The first signal line DL in the lead-out area FA includes two signal line groups DLC symmetrically distributed about the central axis of the binding part BA that is along the second direction Y. The first transfer part CP1 is located between the two signal line groups DLC, and the first bus portion VDM1 and the second bus portion VDM2 of the first power bus VDM are connected through the first transfer part CP1.

As shown in FIG. 7, the second transfer part CP2 and the base body TB1 located in the side area SA can form an integral structure. That is, the second transfer part CP2 can be a portion of the base body TB1 that extends to the lead-out area FA from the side area SA. The first bus portion VSM1 and the second bus portion VSM2 of the second power bus VSM are connected through the second transfer part CP2.

As shown in FIGS. 2 and 7, in some embodiments, the encapsulation base TB can include the base body TB1 located in the side areas SA and the top area TA, at least some sections of the first segments DL1 of at least some of the first signal line DL, and at least some sections of the second segments DL2 of at least some of the first signal line DL.

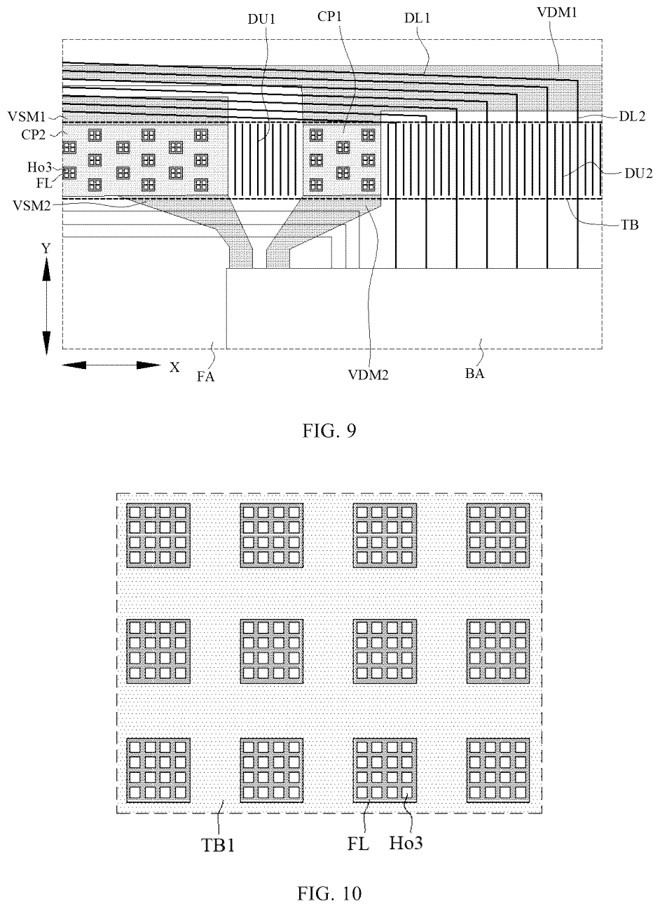

As shown in FIGS. 8 and 9, in some embodiments of the present disclosure, the first segment DL1 of each first signal line DL is located between the transfer part CP and the display area AA, the transfer part CP is located between the first segment DL1 and the binding part BA, and the second segment DL2 of the first signal line DL and the transfer part CP are distributed along the first direction X. Each first signal line DL is divided into two signal line groups DLC symmetrically distributed about the central axis of the binding part BA that is along the second direction Y. The transfer part CP is located outside the two signal line groups DLC.

The encapsulation base TB can include the base body TB1 located in the side areas SA and the top area TA and at least some sections of each second segment DL2.

As shown in FIGS. 8 and 9, in some embodiments, the transfer part CP can include the first transfer part CP1 and the second transfer part CP2 distributed at intervals along the first direction X. The second transfer part CP2 is located between the side regions SA and the first transfer part CP1. The first transfer part CP1, the second transfer part CP2, and the second segment DL2 of the first signal line DL are distributed along the first direction X. The first segment DL1 of the first signal line DL is located between the transfer part CP and the display area AA.

The power bus can include the first power bus VDM and the second power bus VSM. The first bus portion VDM1 of the first power bus VDM is connected to the second bus portion VDM2 of the first power bus VDM through the first transfer part CP1. The first bus portion VSM1 of the second power bus VSM is connected to the second bus portion VSM2 of the second power bus VSM through the second transfer part CP2. The second bus portion VDM2 and the second bus portion VSM2 are both connected to the binding part BA.

As shown in FIGS. 8 and 9, in order to improve the uniformity of the encapsulation base TB, the encapsulation base TB can further include a first dummy part DU1. The first dummy part DUI can be spaced along the first direction X between the first transfer part CP1 and the second transfer part CP2, and the encapsulation adhesive FR can cover the first dummy part DU1. The first dummy part DU1 is provided in a floating manner, that is, the first dummy part DU1 does not receive any electrical signals. The first dummy part DUI can be used to fill the space between the first transfer part CP1 and the second transfer part CP2, making the encapsulation adhesive FR smoother, and further improving the uniformity of the encapsulation adhesive FR, thereby increasing the area of the bonding surface between the encapsulation adhesive FR and the encapsulation base TB, and improving the blocking effect against water and oxygen. The number of the first dummy parts DU1 can be multiple and the multiple first dummy parts DU1 can be distributed at intervals along the first direction X. The first dummy parts DU1 can extend along the second direction Y.

As shown in FIGS. 8 and 9, the circuit layer TL can further include a test line CT, which is at least partially located in the lead-out area FA and connected to the binding part BA. The test line CT can overlap with the second bus portion VDM2 and the second bus portion VSM2, and can be located in the first gate layer GA1 or the second gate layer GA2.

In some embodiments, as shown in FIGS. 7 and 8, at least a portion of the second segments DL2 of at least some of the first signal lines DL belong to the encapsulation base TB, and a second dummy part DU2 can be provided between adjacent two of these second segments DL2. The encapsulation adhesive FR can cover each second dummy part DU2. The second dummy part DU2 can be used to fill the space between two adjacent second segments DL2, making the encapsulation adhesive FR smoother, and further improving the uniformity of the encapsulation adhesive FR, thereby increasing the area of the bonding surface between the encapsulation adhesive FR and the encapsulation base TB, and improving the blocking effect against water and oxygen.

The number of the second dummy parts DU2 can be multiple. The second dummy parts DU2 are provided between two adjacent second segments DL2. The second dummy parts DU2 can be distributed at intervals along the first direction X and extend along the second direction Y.

In some embodiments, the first dummy part DU1 is a linear structure with the same width as the second segment DL2 of the first signal line DL. One or more second dummy parts DU2 are provided between two adjacent second segments DL2, and the spacing between two adjacent second dummy parts DU2 is the same as the spacing between the second dummy part DU2 and its adjacent second segment DL2. In some embodiments, multiple first dummy parts DU1 can be provided between the first transfer part CP1 and the second transfer part CP2, and the spacing between the first dummy parts DU1 is equal to the spacing between the second dummy parts DU2 between the second segments DL2, so that the overall densities of the first dummy parts DU1, the second dummy parts DU2, and the second segments DL2 in the encapsulation base TB are consistent, which is conducive to improving the uniformity of the coverage range of the encapsulation adhesive FR.

As shown in FIG. 13, in some embodiments of the present disclosure, at least a portion of the second segments DL2 belonging to the encapsulation base TB can extend along a bent trajectory, thereby increasing the area of the bonding surface between the encapsulation adhesive FR and the encapsulation base TB, and improving the blocking effect against water and oxygen.

In some embodiments, as shown in FIG. 13, at least a portion of the second segments DL2 belonging to the encapsulation base TB can include a first bent portion WP1 and a second bent portion WP2 that are bent along the first direction X in a reverse manner, and the first bent portion WP1 and the second bent portion WP2 can be alternately distributed along the second direction Y. The shapes of the first bent portion WP1 and the second bent portion WP2 can be unclosed polygons, such as rectangles, or curved shapes such as arcs.

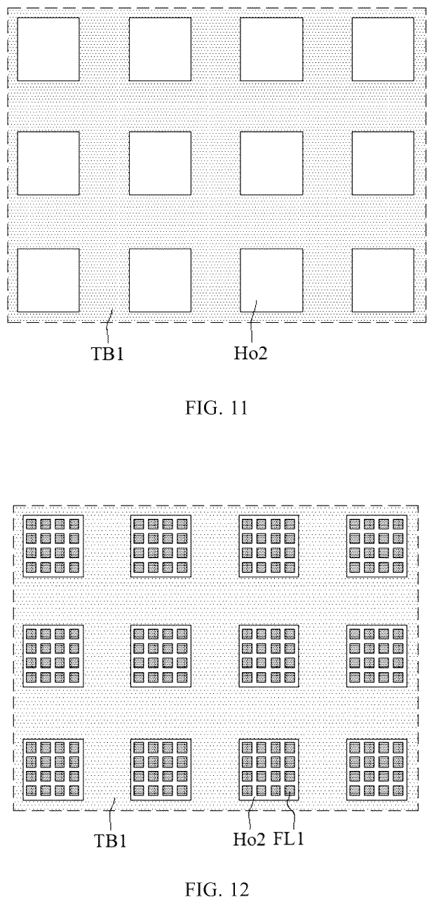

In some embodiments of the present disclosure, as shown in FIGS. 10 and 11, some areas in the encapsulation base TB are provided with second through holes Ho2, and a filling layer FL can be filled in the second through holes Ho2. The filling layer FL is provided with multiple third through holes Ho3. The encapsulation adhesive FR is filled in each third through hole Ho3, thereby increasing the area of the bonding surface between the encapsulation adhesive FR and the encapsulation base TB, and improving the blocking effect against water and oxygen.

In some embodiments, the encapsulation base TB is located in the first gate layer GA1 or the second gate layer GA2, that is, the encapsulation base TB and the first gate layer GA1 or the second gate layer GA2 are arranged in the same layer. The filling layer FL can be formed simultaneously with the interlayer dielectric layer ILD, that is, the filling layer FL and the interlayer dielectric layer ILD are arranged in the same layer.

In some embodiments, there is a distance between the second through hole Ho2 and the boundary of the encapsulation base TB, which can be greater than 30 μm.

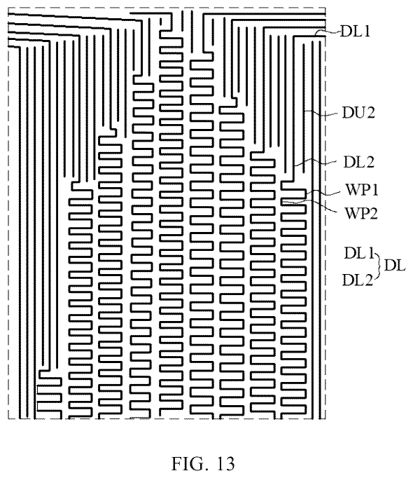

As shown in FIG. 12, in some embodiments of the present disclosure, some areas in the encapsulation base TB are provided with second through holes Ho2, and each second through hole Ho2 can be filled with multiple filling parts FL1. The filling parts FL1 are arranged in an array in the second through hole Ho2, and the encapsulation adhesive FR is filled in the second through hole Ho2 and covers each filling part FL1. By providing the second through hole Ho2 and the filling part FL1, the contact surface with the encapsulation adhesive FR can be increased, and the blocking effect against water and oxygen can be improved.

Embodiments of the present disclosure also provide a display device, which can include the display panel in any of the above embodiments. The display panel can be implemented according to any of the above embodiments, and its specific structure and beneficial effects can refer to the display panel embodiments mentioned above, which will not be repeated here.

The display device disclosed in embodiments of the present disclosure can be electronic devices having display functions such as mobile phones, smartwatches, smart bracelets, tablets, televisions, etc., which will not be listed one by one here.

After considering the specification and practicing of the invention disclosed herein, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are defined by appended claims.

1. A display panel, comprising a display area and a peripheral area located outside the display area, wherein the peripheral area comprises a lead-out area, and the lead-out area comprises a binding part, and wherein the display panel further comprises:
a driving backplane comprising a substrate and a circuit layer arranged on a side of the substrate, wherein the circuit layer comprises an encapsulation base and a power bus that are arranged along a direction away from the substrate, the encapsulation base is arranged in the peripheral area and at least partially surrounds the display area, the power bus is at least partially located in the lead-out area, and a portion of the power bus located in the lead-out area is between the display area and the binding part and is connected to the binding part, and wherein the encapsulation base at most overlaps with the portion of the power bus located in the lead-out area, and the encapsulation base is a reflective structure;
a light-emitting device arranged on a side of the circuit layer away from the substrate, wherein the light-emitting device is located in the display area;
an encapsulation adhesive at least partially provided on a surface of the encapsulation base away from the substrate, wherein the encapsulation adhesive at least partially surrounds the display area along an extension trajectory of the encapsulation base; and
an encapsulation cover plate arranged on a surface of the encapsulation adhesive away from the substrate.

2. The display panel according to claim 1, wherein the encapsulation base comprises a transfer part in the lead-out area, and the power bus comprises a first bus portion and a second bus portion, and
wherein the first bus portion is at least partially located on a side of the transfer part close to the display area, the second bus portion is at least partially located on a side of the transfer part away from the display area and is connected to the binding part, and the first bus portion and the second bus portion are both connected to the transfer part.

3. The display panel according to claim 2, wherein the transfer part comprises a first transfer part and a second transfer part arranged along a first direction in a spaced manner, and the power bus comprises a first power bus and a second power bus, and
wherein a first bus portion of the first power bus and a second bus portion of the first power bus are connected through the first transfer part, and a first bus portion of the second power bus and a second bus portion of the second power bus are connected through the second transfer part.

4. The display panel according to claim 3, wherein the circuit layer further comprises multiple first signal lines, and the first signal lines are at least partially located in the lead-out area and located between the display area and the binding part, and wherein portions of the first signal lines located in the lead-out area comprise first segments extending along the first direction and second segments extending along a second direction intersecting with the first direction, and the second segments are connected to the first segments and the binding part.

5. The display panel according to claim 4, wherein the peripheral area further comprises side areas arranged on both sides of the display area along the first direction and a top area arranged on a side of the display area away from the lead-out area, and the encapsulation base comprises a base body located in the side areas and the top area, at least some sections of the first segments, and at least some sections of the second segments; and
wherein the second segments of the first signal lines comprise two signal line groups symmetrically about a central axis of the binding part that is along the second direction, and the first transfer part is located between the two signal line groups.

6. The display panel according to claim 4, wherein the peripheral area further comprises side areas arranged on both sides of the display area along the first direction and a top area arranged on a side of the display area away from the lead-out area along the second direction; and
wherein the first segments are located between the display area and the first transfer part as well as the second transfer part, and the second segments, the first transfer part, and the second transfer part are distributed along the first direction; and
wherein the encapsulation base comprises a base body located in the side areas and the top area, and at least some sections of the second segments; and
wherein the second segments of the first signal lines are divided into two signal line groups symmetrically about a central axis of the binding part that is along the second direction, and the first transfer part and the second transfer part are located outside the two signal line groups.

7. The display panel according to claim 6, wherein the encapsulation base further comprises a first dummy part, and the first dummy part is arranged between the first transfer part and the second transfer part along the first direction in a spaced manner, and wherein the encapsulation adhesive covers the first dummy part.

8. The display panel according to claim 7, wherein a second dummy part is arranged between the second segments belonging to the encapsulation base, and the encapsulation adhesive covers the second dummy part.

9. The display panel according to claim 8, wherein the first dummy part and the second dummy part both extend along the second direction.

10. The display panel according to claim 6, wherein at least a portion of the second segments belonging to the encapsulation base extend along a bent trajectory.

11. The display panel according to claim 6, wherein at least a portion of the second segments belonging to the encapsulation base comprise a first bent portion and a second bent portion that are bent along the first direction in a reverse manner, and the first bent portion and the second bent portion are alternately distributed along the second direction.

12. The display panel according to claim 1, wherein the circuit layer further comprises multiple first signal lines, and the first signal lines are at least partially located in the lead-out area and located between the display area and the binding part, and wherein portions of the first signal lines located in the lead-out area comprise first segments extending along a first direction and second segments extending along a second direction, and the second segments are connected to the first segments and the binding part; and
wherein the power bus located in the lead-out area comprises a first bus portion extending along the first direction and a second bus portion extending along the second direction, the second bus portion is connected to the first bus portion and the binding part, the first bus portion is located between the first signal lines and the display area, the second bus portion overlaps with the first segments, and the encapsulation adhesive covers the second bus portion.

13. The display panel according to claim 12, wherein the second bus portion is provided with multiple first through holes, and the encapsulation adhesive is filled in the first through holes.

14. The display panel according to claim 12, wherein a width of the second bus portion along the first direction is not greater than 300 μm.

15. The display panel according to claim 1, wherein some areas in the encapsulation base are provided with a second through hole.

16. The display panel according to claim 15, wherein the second through hole is filled with a filling layer, and the filling layer is provided with multiple third through holes, and wherein the encapsulation adhesive is filled in each of the third through holes.

17. The display panel according to claim 1, wherein the circuit layer comprises a first gate layer, a first gate insulation layer, a second gate layer, an interlayer dielectric layer, a first source and drain layer, a first flattened layer, a second source and drain layer, and a second flattened layer that are arranged in sequence along a direction away from the substrate, and the light-emitting device is located on a surface of the second flattened layer away from the substrate; and
wherein the encapsulation base is located in the first gate layer or the second gate layer, and the power bus is located in the first source and drain layer or the second source and drain layer.

18. A display device comprising a display panel wherein the display panel comprises a display area and a peripheral area located outside the display area, the peripheral area comprises a lead-out area, and the lead-out area comprises a binding part, and wherein the display panel further comprises:
a driving backplane comprising a substrate and a circuit layer arranged on a side of the substrate, wherein the circuit layer comprises an encapsulation base and a power bus that are arranged along a direction away from the substrate, the encapsulation base is arranged in the peripheral area and at least partially surrounds the display area, the power bus is at least partially located in the lead-out area, and a portion of the power bus located in the lead-out area is between the display area and the binding part and is connected to the binding part, and wherein the encapsulation base at most overlaps with the portion of the power bus located in the lead-out area, and the encapsulation base is a reflective structure;
a light-emitting device arranged on a side of the circuit layer away from the substrate, wherein the light-emitting device is located in the display area;
an encapsulation adhesive at least partially provided on a surface of the encapsulation base away from the substrate, wherein the encapsulation adhesive at least partially surrounds the display area along an extension trajectory of the encapsulation base; and
an encapsulation cover plate arranged on a surface of the encapsulation adhesive away from the substrate.

19. The display panel according to claim 8, wherein multiple first dummy parts and multiple second dummy parts can be arranged, and a spacing between the first dummy parts is equal to a spacing between the second dummy parts.

20. The display panel according to claim 17, wherein the circuit layer further comprises multiple first signal lines, and the first signal lines are located in the first gate layer or the second gate layer.
